(19) United States
(12) Patent Application Publication
(10) Pub. No.: US 2026/0090406 A1
(43) Pub. Date: Mar. 26, 2026

(54) CHIP MOUNTED SUBSTRATE AND A DISPLAY DEVICE

(71) Applicant: SAMSUNG ELECTRONICS CO., LTD., Suwon-si (KR)

(72) Inventors: Soyoung LIM, Suwon-si (KR); Narae SHIN, Suwon-si (KR)

(73) Assignee: SAMSUNG ELECTRONICS CO., LTD., Suwon-si (KR)

(21) Appl. No.: 19/177,022

(22) Filed: Apr. 11, 2025

(30) Foreign Application Priority Data
Sep. 23, 2024 (KR) 10-2024-0128191

(51) Int. Cl. H01L 23/495; H01L 21/66

(52) U.S. Cl. CPC H10W 70/453; H10P 74/273

(57) ABSTRACT

A chip mounted substrate may include: a film-type substrate including: a first edge region and a second edge region opposing in a first direction; and a third edge region and a fourth edge region connecting the first edge region and the second edge region and opposing in a second direction intersecting the first direction; and a semiconductor chip on the film-type substrate. The film-type substrate may include: an insulating film; chip bonding pads electrically connected to the semiconductor chip; external connection pads electrically connected to the chip bonding pads; and test pads electrically connected to the chip bonding pads and the external connection pads. The test pads may be in at least three of the first edge region, the second edge region, the third edge region, and the fourth edge region.

### CROSS-REFERENCE TO RELATED APPLICATION

This application claims priority to and the benefit of Korean Patent Application No. 10-2024-0128191 filed in the Korean Intellectual Property Office on Sep. 23, 2024, the entire contents of which are incorporated herein by reference.

### BACKGROUND

### (a) Field The present disclosure relates to a chip mounted substrate and a display device.

### (b) Description of the Related Art

A COF (Chip On Film) is a film-type substrate on which a display driver IC (DDI) is attached, and plays a role in connecting the display panel and the printed circuit board (PCB).

Due to demand for high-resolution, multi-function, and high-performance of display devices, film type substrates used for display devices are incorporating an increasing number of external connection pads. Since the size of the film-type substrate is limited and external connection pads are spaced apart by a certain degree, it is important to efficiently arrange the increased number of external connection pads and test pads connected to them.

### SUMMARY

The present disclosure attempts to provide a chip mounted substrate and a display device capable of efficiently arranging the increased external connection pads.

In another aspect, the present disclosure attempts to provide a chip mounted substrate and a display device capable of securing sufficient arrangement space for test pads.

According to one or more example embodiments, a chip mounted substrate may include: a film-type substrate including: a first edge region and a second edge region opposing in a first direction; and a third edge region and a fourth edge region connecting the first edge region and the second edge region and opposing in a second direction intersecting the first direction; and a semiconductor chip on the film-type substrate. The film-type substrate may include: an insulating film; chip bonding pads electrically connected to the semiconductor chip; external connection pads electrically connected to the chip bonding pads; and test pads electrically connected to the chip bonding pads and the external connection pads. The test pads may be in at least three of the first edge region, the second edge region, the third edge region, and the fourth edge region.

According to one or more example embodiments, a chip mounted substrate may include: a film-type substrate including: a chip region; a first bonding region and a second bonding region spaced apart in a first direction with the chip region therebetween; a first edge region adjacent to the second bonding region in the first direction; a second edge region adjacent to the first bonding region in the first direction; and a third edge region and a fourth edge region connecting the first edge region and the second edge region and opposing in a second direction intersecting the first direction; and a semiconductor chip on the chip region of the film-type substrate. The film-type substrate may include: an insulating film including an upper surface opposite a lower surface; upper wiring patterns on the upper surface of the insulating film and including: a first wiring pattern including a first chip bonding pad; a second wiring pattern including a second chip bonding pad; a third wiring pattern including a third chip bonding pad and a first external connection pad; a fourth wiring pattern including a fourth chip bonding pad; and a fifth wiring pattern including a second external connection pad; and lower wiring patterns on the lower surface of the insulating film and including: a sixth wiring pattern electrically connected to the first wiring pattern and including a third external connection pad and a first test pad; a seventh wiring pattern electrically connected to the second wiring pattern and including a fourth external connection pad and a second test pad; an eighth wiring pattern electrically connected to the third wiring pattern and including a third test pad; and a ninth wiring pattern electrically connecting the fourth wiring pattern and the fifth wiring pattern and including a fourth test pad. The first chip bonding pad, the second chip bonding pad, the third chip bonding pad and the fourth chip bonding pad may be in the chip region to be electrically connected to the semiconductor chip, the first external connection pad and the second external connection pad may be in the first bonding region, the third external connection pad and the fourth external connection pad may be in the second bonding region, and the first test pad may be in the first edge region, the third test pad and the fourth test pad may be in the second edge region, and the second test pad is in the third edge region or the fourth edge region.

According to one or more example embodiments, a chip mounted substrate may include: a film-type substrate a first edge and a second edge opposing in a first direction, and a third edge and a fourth edge connecting the first edge and the second edge and opposing in a second direction intersecting the first direction; and a semiconductor chip on a chip region of the film-type substrate. The film-type substrate may include: an insulating film including an upper surface opposite a lower surface; upper wiring patterns on the upper surface of the insulating film and including: a first wiring pattern including a first chip bonding pad; a second wiring pattern including a second chip bonding pad; a third wiring pattern including a third chip bonding pad and a first external connection pad; a fourth wiring pattern including a fourth chip bonding pad, and a fifth wiring pattern including a second external connection pad; and lower wiring patterns on the lower surface of the insulating film, and including: a sixth wiring pattern electrically connected to the first wiring pattern and including a third external connection pad; a seventh wiring pattern electrically connected to the second wiring pattern and including a fourth external connection pad; eighth wiring pattern electrically connected to the third wiring pattern; and a ninth wiring pattern connecting the fourth wiring pattern and the fifth wiring pattern. The first chip bonding pad, the second chip bonding pad, the third chip bonding pad and the fourth chip bonding pad may be in the chip region to be electrically connected to the semiconductor chip, the first external connection pad and the second external connection pad may be in a first bonding region between the second edge and the chip region, the third external connection pad and the fourth external connection pad may be in a second bonding region between the first edge and the chip region, and the sixth wiring pattern extends to the first edge, the eighth wiring pattern and the ninth wiring pattern extend to the second edge, and the seventh wiring pattern extends to the third edge or the fourth edge.

According to an aspect of the present disclosure, a chip mounted substrate and a display device capable of efficiently arranging the increased number of external connection pads can be provided.

According to another aspect of the present disclosure, a chip mounted substrate and a display device capable of securing sufficient arrangement space for test pads can be provided.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a cross-sectional view of a film-type substrate according to one or more embodiments;

FIG. 2 is a cross-sectional view of a film-type substrate according to one or more embodiments;

FIG. 3 is a top view of a film-type substrate according to one or more embodiments;

FIG. 4 is a bottom view of a film-type substrate according to one or more embodiments;

FIG. 5 is a bottom view of a film-type substrate according to one or more embodiments;

FIG. 6 illustrates a wiring path of a film-type substrate according to one or more embodiments;

FIG. 7 illustrates a wiring path of a film-type substrate according to one or more embodiments;

FIG. 8 illustrates a wiring path of a film-type substrate according to one or more embodiments;

FIG. 9 is a cross-sectional view of a chip mounted substrate according to one or more embodiments;

FIG. 10 is a cross-sectional view of a chip mounted substrate after cutting according to one or more embodiments;

FIG. 11 is a top view of the chip mounted substrate illustrated in FIG. 10 according to one or more embodiments;

FIG. 12 is a bottom view of the chip mounted substrate illustrated in FIG. 10 according to one or more embodiments;

FIG. 13 is a cross-sectional view of a display device according to according to one or more embodiments; and

FIG. 14 is a cross-sectional view of a bent portion of a display device according to one or more embodiments.

### DETAILED DESCRIPTION

Hereinafter, with reference to accompanying drawings, various embodiments of the present disclosure will be described in detail so that a person of an ordinary skill can easily implement the present disclosure. The present disclosure may be implemented in many different forms and is not limited to the embodiments described herein.

In order to clearly explain the present disclosure, parts that are not relevant to the description are omitted, and identical or similar components are assigned the same reference numerals throughout the specification.

In addition, the size and thickness of each component shown in the drawings are shown arbitrarily for convenience of explanation, so the present disclosure is not necessarily limited to what is shown. In the drawings, the thickness of layers, films, panels, regions, etc., are exaggerated for clarity. And in the drawings, for convenience of explanation, the thicknesses of some layers and regions are exaggerated.

Throughout the specification, when a part is said to be “connected” to another part, this includes not only “directly connected” but also “indirectly connected” through another member. In a similar sense, this includes being “physically connected”as well as being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, being “on” or “above” a reference element means being positioned on or below the reference element, and does not necessarily mean being positioned “above”or “on”in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “a plane view”, it means that the target portion is viewed from above, and when referring to “a cross-section view”, it means that a cross section of the target portion cut vertically is viewed from a side.

In addition, throughout the specification, sequential numbers such as first and second are used to distinguish a certain component from other components that are the same or similar to the component, and are not necessarily intended to refer to a specific component. Accordingly, a component referred to as a first component in a specific part of this specification may be referred to as a second component in other parts of this specification.

Additionally, throughout the specification, references to a single element include references to a plurality of the element, unless specifically stated to the contrary. For example, “insulating film” may be used to mean not only one insulating film, but also a plurality of insulating films, such as two, three or more.

Additionally, throughout the specification, descriptions of directions such as upper surface, upper side, upper portion, lower surface, lower side, lower portion, etc. are provided for explanation and understanding with reference to the drawings.

Hereinafter, one or more embodiments of the present disclosure will be described with reference to the drawings.

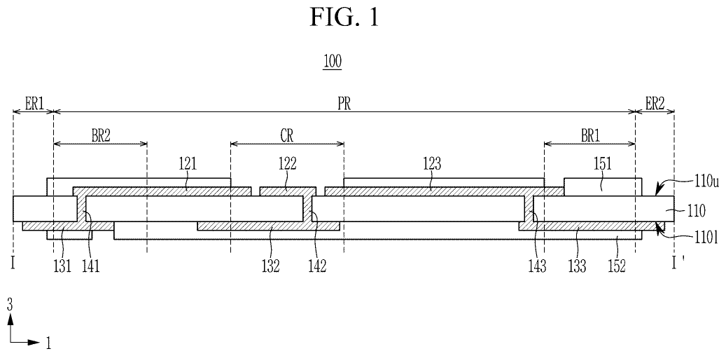

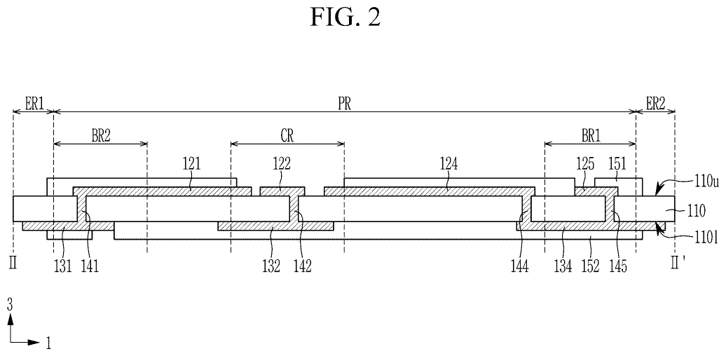

FIG. 1 and FIG. 2 are cross-sectional views of a film-type substrate according to one or more embodiments.

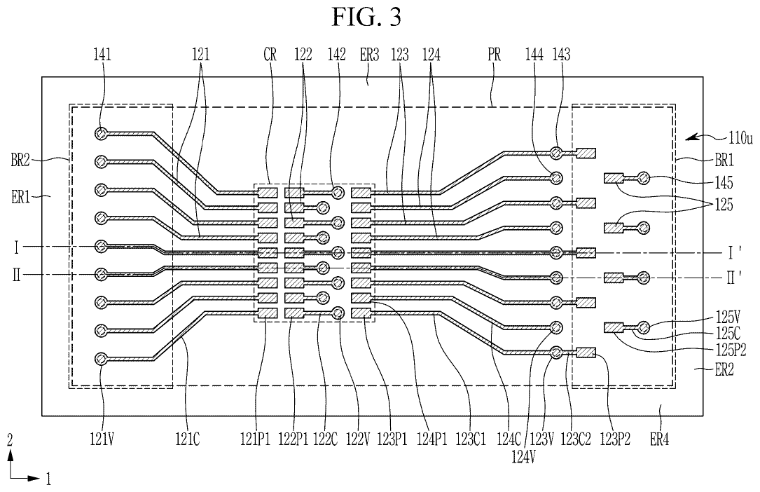

FIG. 3 is a top view of a film-type substrate according to one or more embodiments.

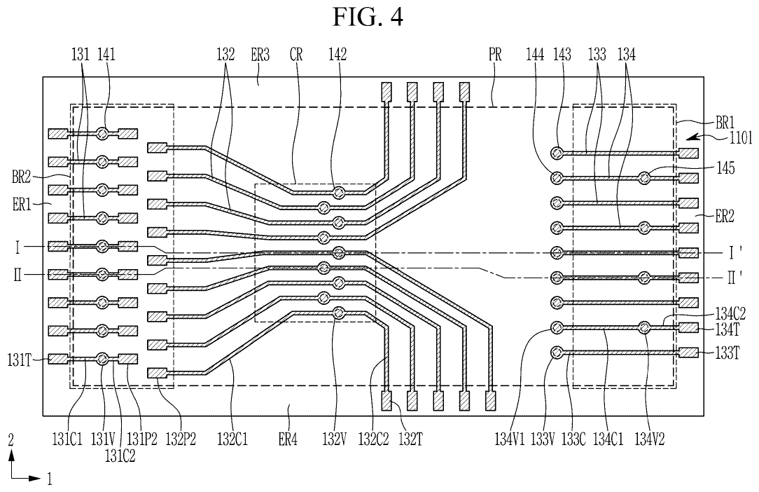

FIG. 4 is a bottom view of a film-type substrate according to one or more embodiments.

FIG. 1 is a cross-sectional view of the film-type substrate of FIG. 3 taken along the line I-I′. FIG. 2 is a cross-sectional view of the film-type substrate of FIG. 3 taken along the line II-II′.

FIG. 3 and FIG. 4 are illustrated excluding the protective layers 151 and 152 in order to clearly show the layout of the wiring patterns.

The film-type substrate 100 has a product region PR and edge regions ER1, ER2, ER3, ER4 surrounding the product region PR, and may include an insulating film 110, upper wiring patterns 121, 122, 123, 124, 125, lower wiring patterns 131, 132, 133, 134, and vias 141, 142, 143, 144, 145.

The product region PR may include a chip region CR, a first bonding region BR1, and a second bonding region BR2. The chip region CR refers to a region overlapping, in a third direction 3, with a region where the semiconductor chip 200 described later is mounted, and the first bonding region BR1 and the second bonding region BR2 refer to a region that overlapping, in the third direction 3, with a region where external components (e.g., printed circuit board (PCB) and display panel) are bonded.

The chip bonding pads 121P1, 122P1, 123P1, 124P1, external connection pads 123P2, 125P2, 131P2, 132P2 and vias 141, 142, 143, 144, 145 may be disposed at the product region PR.

The first bonding region BR1 and the second bonding region BR2 may be separated in a first direction 1 with the chip region CR between them. For example, the first bonding region BR1 and the second bonding region BR2 may be extended to the second direction 2 at both sides of the chip region CR of the first direction 1, respectively. The width of the chip region CR in the second direction 2 may be narrower than the widths of the first bonding region BR1 and the second bonding region BR2 in the second direction 2.

A semiconductor chip 200 may be disposed on the chip region CR. In the chip region CR, chip bonding pads 121P1, 122P1, 123P1, 124P1 electrically connected to the semiconductor chip 200 may be disposed. In one or more embodiments, chip bonding pads 121P1, 122P1, 123P1, 124P1 may be disposed on an upper surface 110u of the insulating film 110.

The first bonding region BR1 may be bonded to a printed circuit board (PCB) 300, and the second bonding region BR2 may be bonded to a display panel 400. The external connection pads 123P2, 125P2 and the external connection pads 131P2, 132P2 may be disposed in the first bonding region BR1 and the second bonding region BR2, respectively. The number of external connection pads 131P2, 132P2 connected to the display panel may be greater than the number of external connection pads 123P2, 125P2 connected to the printed circuit board (PCB).

As described below, the film-type substrate 100 may be present in a display device in a bent state. Considering the bonding positions of the external components in a bent state of the film-type substrate 100, the external connection pads 123P2, 125P2 of the first bonding region BR1 may be disposed on the upper surface 110u of the insulating film 110, and the external connection pads 131P2, 132P2 of the second bonding region BR2 may be disposed on the lower surface 110l of the insulating film 110.

The edge regions ER1, ER2, ER3, ER4 may include a first edge region ER1 and a second edge region ER2 facing each other in the first direction 1, and a third edge region ER3 and a fourth edge region ER4 connecting the first edge region ER1 and the second edge region ER2 and facing each other in the second direction 2 intersecting the first direction 1. Among the edge regions ER1, ER2, ER3, ER4, the first edge region ER1 may be adjacent to the second bonding region BR2 in the first direction 1, and the second edge region ER2 may be an edge adjacent to the first bonding region BR1 in the first direction 1.

The test pads 131T, 132T, 133T, 134T for testing the film-type substrate 100 may be disposed in the edge regions ER1, ER2, ER3, ER4. The test pads 131T, 132T, 133T, 134T may be disposed on the lower surface 110l of the insulating film 110. The test pads 131T, 132T, 133T, 134T may be electrically connected to the chip bonding pads 121P1, 122P1, 123P1, 124P1 and external connection pads 131P2, 132P2, 123P2, 125P2, respectively.

Meanwhile, on demand for high-resolution, multi-function, and high-performance of display device, the number of external connection pads of a film type substrate used therefor is increasing. Since the size of the film-type substrate is limited and appropriate spaces between external connection pads must be secured, it is necessary to efficiently arrange the increased number of external connection pads and test pads connected to them.

The present disclosure attempts to provide a film-type substrate capable of efficiently arranging the external connection pads and securing sufficient arrangement space for test pads connected to the external connection pads. For example, in the present disclosure, the external connection pads 123P2, 125P2 of the first bonding region BR1 and the second external connection pads 131P2, 132P2 of the second bonding region BR2 are arranged in two rows, respectively, so that an increased number of external connection pads can be efficiently arranged. Additionally, in the present disclosure, sufficient arrangement space for test pads may be secured by arranging the test pads 131T, 132T, 133T, 134T in three or more edge regions. For example, the test pads 131T, 132T, 133T, 134T may be disposed not only in the first edge region ER1 and the second edge region ER2, but also in the third edge region ER3 and the fourth edge region ER4 for avoiding congestion in the first edge region ER1 and the second edge region ER2.

Hereinafter, a film-type substrate 100 according to one or more embodiments of the present disclosure, including specific connection paths of wiring patterns, will be described in more detail.

The insulating film 110 has an upper surface 110u and a lower surface 110l, which are opposite surfaces.

The insulating film 110 may be a bendable flexible film. As a material for insulating film 110, for example, polyimide may be used.

The upper wiring patterns 121, 122, 123, 124, 125 may include first wiring pattern(s) 121, second wiring pattern(s) 122, third wiring pattern(s) 123, fourth wiring pattern(s) 124 and fifth wiring pattern(s) 125.

The lower wiring patterns 131, 132, 133, 134 may include sixth wiring pattern(s) 131, seventh wiring pattern(s) 132, eighth wiring pattern(s) 133 and ninth wiring pattern(s) 134.

The first wiring pattern 121 and the sixth wiring pattern 131 may be connected to each other to form a first wire, the second wiring pattern 122 and the seventh wiring pattern 132 may be connected to each other to form a second wire, the third wiring pattern 123 and the eighth wiring pattern 133 may be connected to each other to form a third wire, and the fourth wiring pattern 124, the fifth wiring pattern 125, and the ninth wiring pattern 134 may be connected to each other to form a fourth wire.

The first wiring pattern 121 includes a first chip bonding pad 121P1, a first via pad 121V, and a connection pattern 121C, and may be extended from the first chip bonding pad 121P1 to the first edge region ER1. The first wiring patterns 121 may be arranged in the second direction 2.

The first chip bonding pad 121P1 is disposed in the chip region CR and may be electrically connected to the semiconductor chip 200. The first chip bonding pads 121P1 may be disposed adjacent to the first edge region ER1, compared to the second chip bonding pads 122P1. Additionally, the first chip bonding pads 121P1 may be arranged in the second direction 2.

The first via pad 121V may be connected to the first via 141. The first via pad 121V overlaps the first via 141 in third direction 3 and may contact the first via 141. For stable connection with the first via 141, the diameter of first via pad 121V may be larger than the diameter of first via 141.

The connection pattern 121C is extended from the first chip bonding pad 121P1 to the first via pad 121V and may connect them each other.

The second wiring pattern 122 includes a second chip bonding pad 122P1, a second via pad 122V, and a connection pattern 122C, and may be extended from the second chip bonding pad 122P1 to the second edge region ER2. The second wiring pattern 122 may be extended in the second direction 2.

The second chip bonding pad 122P1 is disposed in the chip region CR and may be electrically connected to the semiconductor chip 200. The second chip bonding pads 122P1 may be spaced apart from the first chip bonding pads 121P1 in the first direction 1 so as to be arranged farther from the first edge region ER1 compared to the first chip bonding pads 121P1. For example, the second chip bonding pads 122P1 may be disposed between the first chip bonding pads 121P1 and the third chip bonding pads 123P1. By arranging the first chip bonding pads 121P1 and the second chip bonding pads 122P1 in two rows, it is possible to arrange a plurality of chip bonding pads 121P1, 122P1 connected to external connection pads 131P2, 132P2 while securing an appropriate spacing between the chip bonding pads 121P1, 122P1. Also, the second chip bonding pads 122P1 may be arranged in the second direction 2.

The second via pad 122V may be connected to the second via 142. The second via pad 122V overlaps the second via 142 in third direction 3 and may contact the second via 142. For stable connection with the second via 142, the diameter of the second via pad 122V may be larger than the diameter of the second via 142. The second via pads 122V may be arranged along the second direction 2. At this time, the second via pads 122V adjacent to each other may be arranged misaligned along the second direction 2 for efficient arrangement, and the second via pads 122V may form an approximate zigzag shape.

The connection pattern 122C may be extended from the second chip bonding pad 122P1 to the second via pad 122V and may connect them each other.

The third wiring pattern 123 includes a third chip bonding pad 123P1, a third via pad 123V, a first external connection pad 123P2, and connection patterns 123C1, 123C2, and may be extended from the third chip bonding pad 123P1 to the second edge region ER2.

The third chip bonding pad 123P1 is disposed in the chip region CR and may be electrically connected to the semiconductor chip 200. The third chip bonding pads 123P1 may be spaced apart from the first chip bonding pads 121P1 and the second chip bonding pads 122P1 in the first direction 1 so as to be arranged more adjacent (closer) to the second edge region ER2 compared to the first chip bonding pads 121P1 and the second chip bonding pads 122P1. Also, the third chip bonding pads 123P1 may be arranged in the second direction 2.

The third via pad 123V may be connected to the third via 143. The third via pad 123V overlaps the third via 143 in third direction 3 and may contact the third via 143. For stable connection with the third via 143, the diameter of third via pad 123V may be larger than the diameter of the third via 143.

The first external connection pad 123P2 is disposed in the first bonding region BR1 and may be connected to an external component, for example, a printed circuit board (PCB) 300 described below. The first external connection pads 123P2 may be disposed more adjacent to the chip region CR compared to the second external connection pads 125P2. Also, the first external connection bonding pads 123P2 may be arranged in the second direction 2.

The connection patterns 123C1, 123C2 may connect the third chip bonding pad 123P1, the third via pad 123V and the first external connection pad 123P2 one another. For example, the connection pattern 123C1 may be extended from the third chip bonding pad 123P1 to the third via pad 123V to connect them each other, and connection pattern 123C2 may be extended from the third via pad 123V to the first external connection pad 123P2 to connect them each other.

The fourth wiring pattern 124 includes a fourth chip bonding pad 124P1, a fourth via pad 124V, and a connection pattern 124C, and may be extended from the third chip bonding pad 123P1 to the second edge region ER2. The fourth wiring patterns 124 may be arranged in the second direction 2, and may be alternately arranged with the third wiring patterns 123 in the second direction 2.

The fourth chip bonding pad 124P1 may be electrically connected to the semiconductor chip 200. The fourth chip bonding pads 124P1 may be spaced apart from the first chip bonding pads 121P1 and the second chip bonding pads 122P1 in the first direction 1 so as to be arranged more adjacent to the second edge region ER2 compared to the first chip bonding pads 121P1 and the second chip bonding pads 122P1. The fourth chip bonding pads 124P1 may be arranged in the second direction 2, and may be, for example, alternately arranged with the third chip bonding pads 123P1 in the second direction 2.

The fourth via pad 124V may be connected to the fourth via 144. The fourth via pad 124V overlaps the fourth via 144 in third direction 3 and may contact the fourth via 144. For stable connection with the fourth via 144, the diameter of fourth via pad 124V may be larger than the diameter of fourth via 144.

The connection pattern 124C is extended from the fourth chip bonding pad 124P1 to the fourth via pad 124V and may connect them each other.

The fifth wiring pattern 125 includes a second external connection pad 125P2, a fifth via pad 125V, and a connection pattern 125C, and may be extended from the second external connection pad 125P2 to the second edge region ER2. The fifth wiring patterns 125 may be arranged in the second direction 2.

The fifth wiring pattern 125 may be connected to the fourth wiring pattern 124 through the ninth wiring pattern 134, and considering the position of the ninth wiring pattern, the fifth wiring pattern 125 may be disposed more adjacent to the second edge region ER2 compared to the fourth wiring pattern 124.

The second external connection pad 125P2 is disposed in the first bonding region BR1 and may be connected to an external component, for example, a printed circuit board (PCB) 300 described below. The second external connection pads 125P2 may be disposed farther from the chip region CR compared to the first external connection pads 123P2. Also, the second first external connection bonding pads 125P2 may be arranged in the second direction 2.

In the present disclosure, the first external connection pads 123P2 and the second external connection pads 125P2 may form two rows. At this time, the first external connection pad 123P2 and the second external connection pad 125P2 may be arranged misaligned along the first direction 1 (i.e. offset in the second direction 2) for securing wiring space connected to them (see FIG. 3) to form a zigzag shape. However, not limited thereto, the first external connection pad 123P2 and the second external connection pad 125P2 may be arranged along the first direction 1 to be disposed parallel to each other. By arranging the first external connection pads 123P2 and the second external connection pads 125P2 in two rows, a plurality of external connection pads 123P2, 125P2 may be arranged while ensuring an appropriate spacing between the external connection pads 123P2, 125P2.

The sixth wiring pattern 131 includes a first test pad 131T, a sixth via pad 131V, a third external connection pad 131P2 and connection, and may bifurcate from the sixth via pad 131V toward both sides, for example, toward both side in the first direction 1. The sixth wiring patterns 131 may be arranged in the second direction 2.

The first test pad 131T may be disposed in the first edge region ER1. The first test pad 131T is connected to the first chip bonding pad 121P1 and the third external connection pad 131P2 and may be used for electrical test of the film-type substrate 100. The first test pads 131T may be arranged in the second direction 2 along the first edge region ER1.

The sixth via pad 131V may be connected to the first via 141. The sixth via pad 131V overlaps the first via 141 in third direction 3 and may contact the first via 141. For stable connection with the first via 141, the diameter of sixth via pad 131V may be larger than the diameter of first via 141.

The third external connection pad 131P2 is disposed in the second bonding region BR2 and may be connected to an external component, for example, a display panel 400 described below. The third external connection pads 131P2 may be disposed farther from the chip region CR compared to the fourth external connection pads 132P2. Also, the third first external connection bonding pads 131P2 may be arranged in the second direction 2.

The connection patterns 131C1, 131C2 may connect first test pad 131T, sixth via pad 131V and the third external connection pad 131P2 one another. For example, the connection pattern 131C1 may be extended from the first test pad 131T to the sixth via pad 131V to connect them each other, and connection pattern 131C2 may be extended from the sixth via pad 131V to the third external connection pad 131P2 to connect them each other.

The seventh wiring pattern 132 includes a fourth external connection pad 132P2, seventh via pad 132V, second test pad 132T and connection patterns 132C1, 132C2, and may bifurcate from the seventh via pad 132V toward both sides, for example, toward both side in the first direction 1. The seventh wiring patterns 132 may be disposed between sixth wiring patterns 131 and eighth wiring patterns 133 in the first direction 1 (also understood as between the sixth wiring patterns 131 and the ninth wiring patterns 134).

The fourth external connection pad 132P2 is disposed in the second bonding region BR2 and may be connected to an external component, for example, a display panel 400 described below. The fourth external connection pads 132P2 may be disposed more adjacent to the chip region CR compared to the third external connection pads 131P2. Also, the fourth first external connection bonding pads 132P2 may be arranged in the second direction 2.

In the present disclosure, the third external connection pads 131P2 and the fourth external connection pads 132P2 may form two rows. At this time, the third external connection pad 131P2 and the fourth external connection pad 132P2 may be arranged misaligned along the first direction 1 (i.e. offset in the second direction 2) for securing wiring space connected to them (see FIG. 4) to form a zigzag shape. However, not limited thereto, the third external connection pad 131P2 and the fourth external connection pad 132P2 may be arranged along the first direction 1 to be disposed parallel to each other. By arranging the third external connection pads 131P2 and the fourth external connection pads 132P2 in two rows, a plurality of external connection pads 131P2, 132P2 may be arranged while ensuring an appropriate spacing between the external connection pads 131P2, 132P2.

The seventh via pad 132V may be connected to the second via 142. The seventh via pad 132V overlaps the second via 142 in third direction 3 and may contact the second via 142. For stable connection with the second via 142, the diameter of the seventh via pad 132V may be larger than the diameter of the second via 142.

The second test pads 132T may be disposed in at least one of the third edge region ER3 and the fourth edge region ER4. Each of the second test pads 132T may be disposed in the third edge region ER3 or the fourth edge region ER4. The second test pad 132T is connected to the second chip bonding pad 122P1 and the fourth external connection pad 132P2 and may be used for electrical test of the film-type substrate 100. In one or more embodiments, the second test pads 132T may be arranged dividedly in the third edge region ER3 and the fourth edge region ER4. The second test pads 132T may be arranged in the first direction 1 along the third edge region ER3 and the fourth edge region ER4.

The connection patterns 132C1 and 132C2 may connect the fourth external connection pad 132P2, the seventh via pad 132V and the second test pad 132T one another. For example, the connection pattern 132C1 may be extended from the connection pad 132P2 to the seventh via pad 132V to connect them each other, and connection pattern 132C2 may be extended from the seventh via pad 132V to the second test pad 132T to connect them each other.

The eighth wiring pattern 133 may be a wiring path for testing the third chip bonding pad 123P1 and the first external connection pad 123P2 of the third wiring pattern 123.

The eighth wiring pattern 133 includes an eighth via pad 133V, a third test pad 133T and a connection pattern 133C and may be extended from the eighth via pad 133V to the third test pad 133T. The eighth wiring patterns 133 may be arranged in the second direction 2.

The eighth via pad 133V may be connected to the third via 143. The eighth via pad 133V overlaps the third via 143 in third direction 3 and may contact the third via 143. For stable connection with the third via 143, the diameter of eighth via pad 133V may be larger than the diameter of the third via 143.

The third test pad 133T may be disposed in the second edge region ER2. The third test pad 133T is connected to the third chip bonding pad 123P1 and the first external connection pad 123P2 and may be used for electrical test of the film-type substrate 100. The third test pad 133T may be arranged in the second direction 2 along the second edge region ER2.

The connection pattern 133C is extended from the eighth via pad 133V to the third test pad 133T to connect them each other.

The ninth wiring pattern 134 may connect to the fourth wiring pattern 124 and the fifth wiring pattern 125. The ninth wiring pattern 134 connects the fourth chip bonding pad 124P1 of the fourth wiring pattern 124 and the second external connection pad 125P2 of the fifth wiring pattern 125 to provide a test path for them. In addition, the ninth wiring pattern 134 provides a connection path between the fourth chip bonding pad 124P1 and the second external connection pad 125P2 through the lower surface 110l of the insulating film 110, thereby may complement the wiring congestion and the limit of wiring space on the upper surface 110u of the insulating film 110.

The ninth wiring pattern 134 includes a ninth via pad 134V1, a tenth via pad 134V2, a fourth test pad 134T, and connection patterns 134C1, 134C2, and may be extended from the ninth via pad 134V1 to the fourth test pad 134T. The ninth wiring patterns 134 may be arranged in the second direction 2, and may be alternately arranged with the eighth wiring patterns 133 in the second direction 2.

The ninth via pad 134V1 may be connected to the fourth via 144. The ninth via pad 134V1 overlaps the fourth via 144 in third direction 3 and may contact the fourth via 144. For stable connection with the fourth via 144, the diameter of ninth via pad 134V1 may be larger than the diameter of fourth via 144.

The tenth via pad 134V2 may be connected to the fifth via 145. The tenth via pad 134V2 overlaps the fifth via 145 in third direction 3 and may contact the fifth via 145. For stable connection with the fifth via 145, the diameter of tenth via pad 134V2 may be larger than the diameter of the fifth via 145.

The fourth test pad 134T may be disposed in the second edge region ER2. The fourth test pad 134T is connected to the first chip bonding pad 121P1 and the second external connection pad 125P2 and may be used for electrical test of the film-type substrate 100. The fourth test pads 134T may be arranged in the second direction 2 along the second edge region ER2, and for example may be alternately arranged with the third test pads 133T in the second direction 2.

The connection patterns 134C1, 134C2 may connect the ninth via pad 134V1, the tenth via pad 134V2, and the fourth test pad 134T one another. For example, the connection pattern 134C1 may be extended from the ninth via pad 134V1 to the tenth via pad 134V2 to connect them each other, and connection pattern 134C2 may be extended from the tenth via pad 134V2 to the fourth test pad 134T to connect them each other.

Each of the vias 141, 142, 143, 144, 145 penetrates the insulating film 110 and may connect the upper wiring pattern 121, 122, 123, 124, 125 and the lower wiring pattern 131, 132, 133, 134.

The vias 141, 142, 143, 144, 145 may include a first via 141 connecting the first wiring pattern 121 and the sixth wiring pattern 131, a second via 142 connecting the second wiring pattern 122 and the seventh wiring pattern 132, a third via 143 connecting the third wiring pattern 123 and the eighth wiring pattern 133, a fourth via 144 connecting the fourth wiring pattern 124 and the ninth wiring pattern 134, and a fifth via 145 connecting the fifth wiring pattern 125 and the ninth wiring pattern 134.

As material for the wiring patterns 121, 122, 123, 124, 125, 131, 132, 133, 134 and the vias 141, 142, 143, 144, 145, for example, Copper (Cu) , Aluminum (AL), etc. may be used.

The film-type substrate 100 may further include protective layers 151 and 152 disposed on both surfaces of the insulating film 110 to protect the wiring patterns 121, 122, 123, 124, 125, 131, 132, 133, 134.

The first protective layer 151 may be disposed on the upper surface 110u of the insulating film 110 to cover the upper wiring patterns 121, 122, 123, 124, 125. Also, the first protection layer 151 may expose at least a portion of each of the chip bonding pads 121P1, 122P1, 123P1, 124P1 and external connection pads 123P2, 125P2 for external connection.

The second protective layer 152 may be disposed on the lower surface 110l of the insulating film 110 to cover the lower wiring patterns 131, 132, 133, 134. Also, the second protection layer 152 may expose at least a portion of each of the test pads 131T, 132T, 133T, 134T and external connection pads 131P2, 132P2 for external connection.

As material for the protective layers 151 and 152, insulating material such as solder resist may be used.

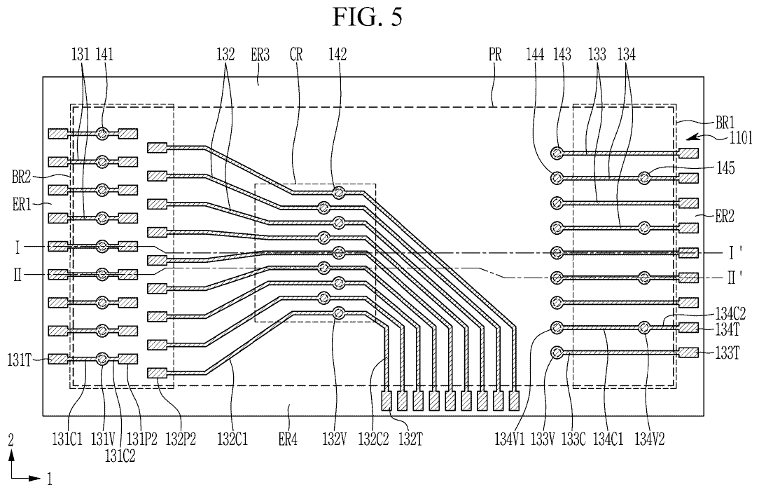

FIG. 5 is a bottom view of a film-type substrate according to another embodiment.

In one or more embodiments, the second test pads 132T may be arranged in only one of the third edge region ER3 and the fourth edge region ER4. That is, the second test pads 132T may not be disposed in the third edge region ER3, and may disposed only in the fourth edge region ER4. Alternatively, the second test pads 132T may be placed only in the third edge region ER3 and may not disposed in the fourth edge region ER4.

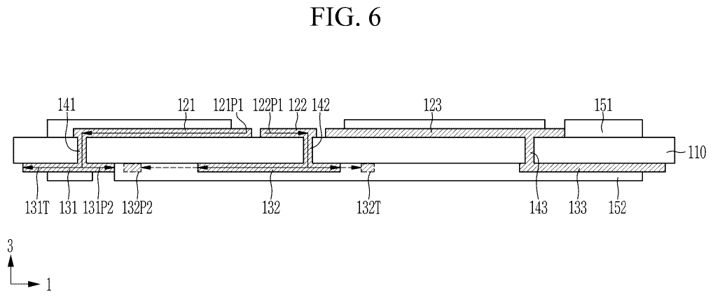

FIG. 6 to FIG. 8 illustrate wiring paths of a film-type substrate according to one or more embodiments.

Referring to FIG. 6 first, the signal input to the first chip bonding pad 121P1 may be transmitted to the sixth wiring pattern 131 through the first via 141 to be output to the first test pad 131T and the third external connection pad 131P2.

Also, the signal input to the second chip bonding pad 122P1 may be transmitted to the seventh wiring pattern 132 through the second via 142 to be output to the second test pad 132T and the fourth external connection pad 132P2.

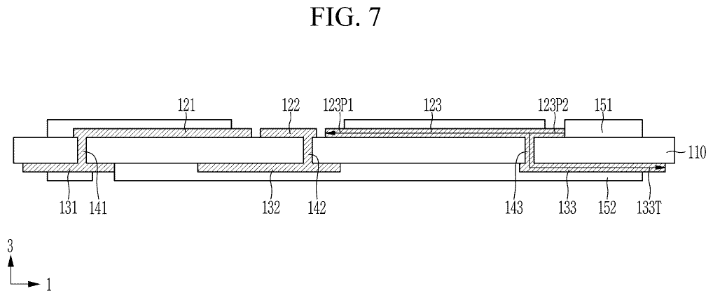

Referring to FIG. 7, the signal input to the first external connection pad 123P2 is output to the third chip bonding pad 123P1, and may be transmitted to the eighth wiring pattern 133 through the third via 143 to be output to the third test pad 133T.

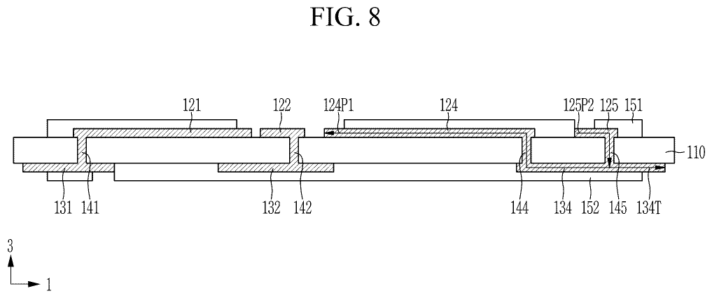

Referring to FIG. 8, the signal input to the second external connection pad 125P2 may be transmitted to the ninth wiring pattern 134 through the fifth via 145 to be output to the fourth test pad 134T, and may be transmitted to the fourth wiring pattern 124 through the fourth via 144 connected to the ninth wiring pattern 134 to be output to the fourth chip bonding pad 124P1.

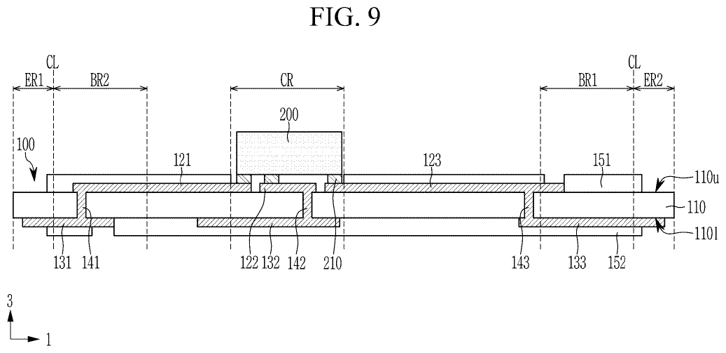

FIG. 9 is a cross-sectional view of a chip mounted substrate according to one or more embodiments.

A chip mounted substrate according to one or more embodiments may include a film-type substrate 100 and a semiconductor chip 200. In the technical field to which the present disclosure belongs, the chip mounted substrate may be referred to as a chip on film (COP).

The semiconductor chip 200 may be disposed on a chip region CR of the film-type substrate 100. For example, the semiconductor chip 200 may be disposed on the upper surface 110u of the insulating film 110 and connected to the chip bonding pads 121P1, 122P1, 123P1, 124P1.

The semiconductor chip 200 may include chip pads arranged corresponding to the chip bonding pads 121P1, 122P1, 123P1, 124P1. The semiconductor chip 200 may be mounted on the film-type substrate 100 through conductive bumps 210 disposed between the chip pads and the chip bonding pads 121P1, 122P1, 123P1, 124P1.

The semiconductor chip 200 may include a display driver IC (DDI).

For other configurations, the same descriptions as set forth in the present disclosure may be applied.

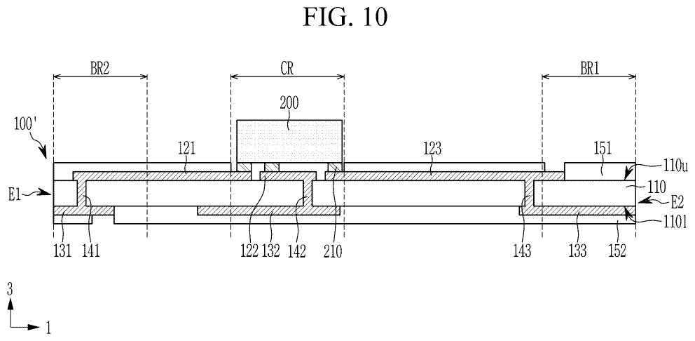

FIG. 10 is a cross-sectional view of a chip mounted substrate after cutting according to one or more embodiments.

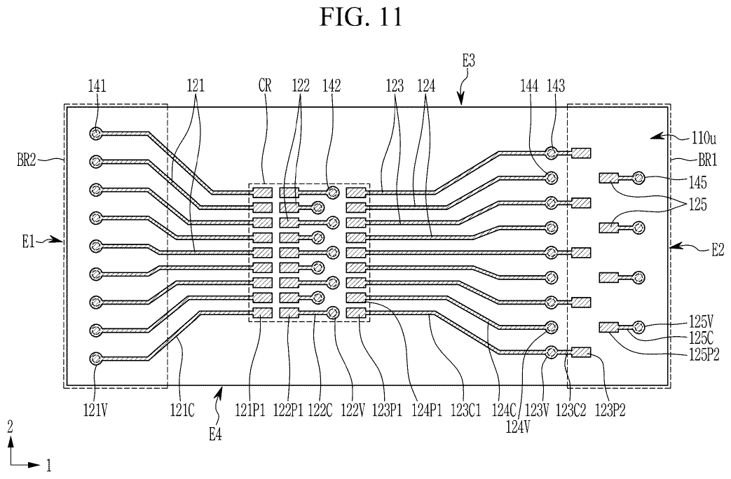

FIG. 11 is a top view of the chip mounted substrate illustrated in FIG. 10.

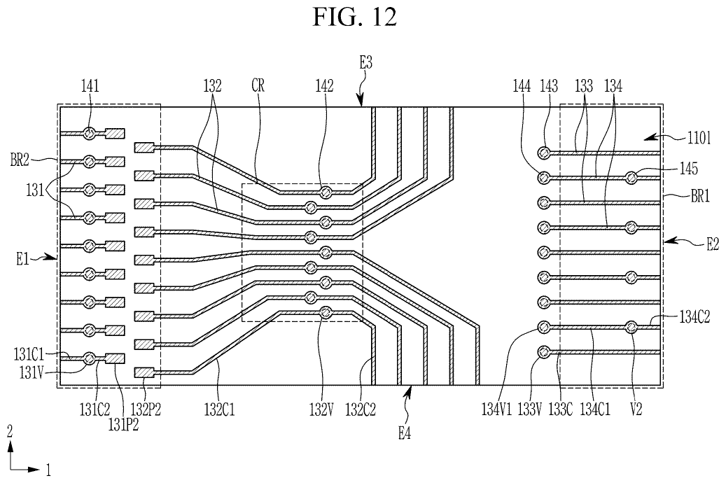

FIG. 12 is a bottom view of the chip mounted substrate illustrated in FIG. 10.

FIG. 11 and FIG. 12 are illustrated excluding the protective layers 151 and 152 in order to clearly show the layout of the wiring patterns.

The chip mounted substrate is cut along the cutting line (CL) of FIG. 9 and may be used for a display device. Since the cutting line (CL) is positioned between the product region PR and the edge regions ER1, ER2, ER3, ER4, the edge regions ER1, ER2, ER3, ER4 of the film-type substrate 100 are removed after cutting.

For example, the sixth wiring patterns 131 of the film-type substrate 100′ may be a form that the connection pattern 131C1 and the first test pad 131T, which are disposed in the first edge region ER1, are removed in part. Also, the seventh wiring patterns 132 may be a form that the second test pad 132T and the connection pattern 132C2, which are disposed in the third edge region ER3 and the fourth edge region ER4, are removed in part. Additionally, the eighth wiring patterns 133 may be a form that the connection pattern 133C and the third test pad 133T disposed in the second edge region ER2 are removed in part, and the ninth wiring patterns 134 may be a form that the connection pattern 134C2 and the fourth test pad 134T disposed in the second edge region ER2 are removed in part.

The edges exposed by removing the first edge region ER1, the second edge region ER2, the third edge region ER3, and the fourth edge region ER4 of the film-type substrate 100 may form the first edge E1, the second edge E2, the third edge E3, and the fourth edge E4 of the film-type substrate 100', respectively.

Thus, the first bonding region BR1 may be disposed between the second edge E2 and chip region CR, and the second bonding region BR2 may be disposed between the first edge E1 and the chip region CR.

Additionally, the sixth wiring patterns 131 (e.g., connection pattern 131C1) of the film-type substrate 100′ may be extended to the first edge E1, the eighth wiring patterns 133 (e.g., connection pattern 133C) and the ninth wiring patterns 134 (e.g., connection pattern 134C2) may be extended to the second edge E2, and the seventh wiring patterns 132 (e.g., connection pattern 132C2) may be extended to at least one of the third edge E3 and the fourth edge E4. Each of the seventh wiring pattern 132 may be extended to the third edge E3 or the fourth edge E4.

For other configurations, the same descriptions as set forth in the present disclosure may be applied.

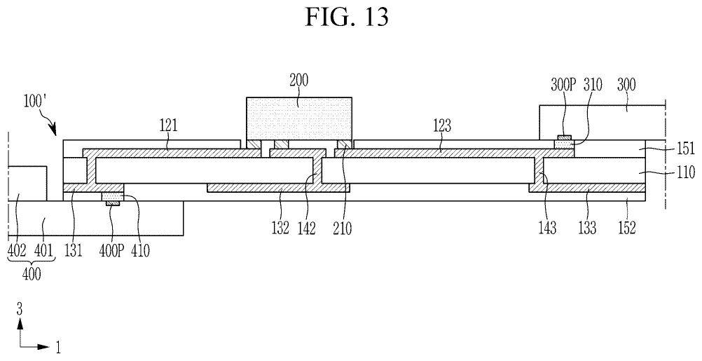

FIG. 13 is a cross-sectional view of a display device according to one or more embodiments.

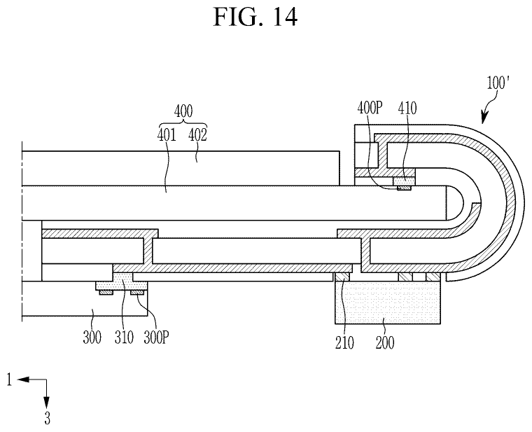

FIG. 14 is a cross-sectional view of a bent portion of a display device according to one or more embodiments.

The display device may include a film-type substrate 100′ and one or more chip mounted substrates including a semiconductor chip 200, a printed circuit board (PCB) 300, and a display panel 400.

In one or more embodiments, the display device may include a plurality of chip mounted substrates connected to the printed circuit board (PCB) 300 and the display panel 400, and the plurality of the chip mounted substrates may be spaced apart from each other in the second direction 2. The chip mounted substrate may receive signals input from the printed circuit board (PCB) 300 and output them to the display panel 400.

At least a part of the printed circuit board (PCB) 300 may be disposed on the first bonding region BR1 of the film-type substrate 100'. For example, the printed circuit board (PCB) 300 may be disposed on the upper surface 110u of the insulating film 110 together with the semiconductor chip 200 in the first bonding region BR1 of a film-type substrate 100'. Additionally, the printed circuit board (PCB) 300 may be extended outside the film-type substrate 100′.

The printed circuit board (PCB) 300 may be connected to the first external connection pad 123P2 and the second external connection pad 125P2. The printed circuit board (PCB) 300 may have connection pads 300P, and may be electrically connected to the external connection pads 123P2, 125P2 through the connection pads 300P.

The printed circuit board (PCB) 300 may be bonded through a film-type substrate 100′ and a connecting member 310. The connecting member 310 may be, for example, an anisotropic conductive film (ACF) or an anisotropic conductive paste (ACP).

At least a part of the display panel 400 may be disposed on the second bonding region BR2 of the film-type substrate 100′. For example, the printed circuit board (PCB) 300 may be disposed on the lower surface 110l of the insulating film 110 in a second bonding region BR2 of a film-type substrate 100′. Also, the display panel 400 may be extended outside the film-type substrate 100′.

The display panel 400 may be connected to the third external connection pad 131P2 and the fourth external connection pad 132P2. The display panel 400 may have connection pads 400P, and may be electrically connected to the external connection pads 131P2, 132P2 through the connection pad 400P.

The display panel 400 may be bonded through the film-type substrate 100′ and the connecting member 410. The connecting member 410 may be, for example, a anisotropic conductive film (ACF) or a anisotropic conductive paste (ACP).

The display panel 400 may include a substrate 401 and a display region 402 disposed on the substrate 401.

The substrate 401 may connect the film-type substrate 100′ and the display region 402. The substrate 401 may be, for example, a glass substrate.

The display region 402 is disposed on the substrate 401, and may be disposed, for example, on a surface on which the film-type substrate 100′ of the substrate 401 is disposed. In the display region 402, pixels for implementing a display may be disposed.

The display panel 400 may include at least one of an LED (Light Emitting Diode) panel, micro(micro) LED panel, OLED (Organic Light Emitting Diode) panel, micro OLED panel, AMOLED (Active Matrix OLED) panel, plasma display panel (plasma display panel; PDP), and an LCD (Liquid Crystal Display) panel.

Referring to FIG. 14, in the display device, the film-type substrate 100′ may be bendable. For example, a film-type substrate 100′ may be bent in a region between a chip region CR and a second bonding region BR2 so that a display panel 400 faces a semiconductor chip 200 and a printed circuit board (PCB) 300.

A display device including a bent film-type substrate 100′ may be suitable to be used in small electronic products such as mobile phones.

For other configurations, the same descriptions as set forth in the present disclosure may be applied.

Although the embodiments of the present disclosure have been described in detail above, the scope of the present disclosure is not limited thereto, and various modifications and improvements can be made by those skilled in the art using the basic concept of the present disclosure defined in the following claims, and they fall within the scope of the present disclosure.

Additionally, the embodiments of the present disclosure are not independent of each other and may be implemented in combination with each other unless specifically contradictory. Therefore, the combinations of the embodiments of the present disclosure should also be considered as included in the present disclosure.

What is claimed is:

1. A chip mounted substrate comprising:
a film-type substrate comprising:
a first edge region and a second edge region opposing in a first direction; and
a third edge region and a fourth edge region connecting the first edge region and the second edge region and opposing in a second direction intersecting the first direction; and
a semiconductor chip on the film-type substrate,
wherein the film-type substrate comprises:
an insulating film;
chip bonding pads electrically connected to the semiconductor chip;
external connection pads electrically connected to the chip bonding pads; and
test pads electrically connected to the chip bonding pads and the external connection pads, and
wherein the test pads are in at least three of the first edge region, the second edge region, the third edge region, and the fourth edge region.

2. The chip mounted substrate of claim 1,
wherein the film-type substrate further comprises a chip region, a first bonding region, and a second bonding region, wherein the first edge region, the second edge region, the third edge region and the fourth edge region are around the chip region, the first bonding region, and the second bonding region,
wherein the chip bonding pads are in the chip region, and
wherein the external connection pads comprise a first external connection pad in the first bonding region and a second external connection pad in the second bonding region.

3. The chip mounted substrate of claim 2,
wherein the first bonding region and the second bonding region are spaced apart in the first direction with the chip region therebetween.

4. The chip mounted substrate of claim 3,
wherein the test pads comprise a first test pad in the first edge region and a second test pad in the second edge region.

5. The chip mounted substrate of claim 2, wherein the external connection pads further comprise:
a third external connection pad in the first bonding region and closer to the chip region than the first external connection pad; and a fourth external connection pad in the second bonding region and closer to the chip region than the second external connection pad.

6. The chip mounted substrate of claim 2,
wherein the chip bonding pads and the first external connection pad are on an upper surface of the insulating film; and
wherein the second external connection pad and the test pads are on a lower surface of the insulating film.

7. A chip mounted substrate comprising:
a film-type substrate comprising:
a chip region;
a first bonding region and a second bonding region spaced apart in a first direction with the chip region therebetween;
a first edge region adjacent to the second bonding region in the first direction;
a second edge region adjacent to the first bonding region in the first direction; and
a third edge region and a fourth edge region connecting the first edge region and the second edge region and opposing in a second direction intersecting the first direction; and
a semiconductor chip on the chip region of the film-type substrate,
wherein the film-type substrate comprises:
an insulating film comprising an upper surface opposite a lower surface;
upper wiring patterns on the upper surface of the insulating film and comprising:
a first wiring pattern comprising a first chip bonding pad;
a second wiring pattern comprising a second chip bonding pad;
a third wiring pattern comprising a third chip bonding pad and a first external connection pad;
a fourth wiring pattern comprising a fourth chip bonding pad; and
a fifth wiring pattern comprising a second external connection pad; and
lower wiring patterns on the lower surface of the insulating film and comprising:
a sixth wiring pattern electrically connected to the first wiring pattern and comprising a third external connection pad and a first test pad;
a seventh wiring pattern electrically connected to the second wiring pattern and comprising a fourth external connection pad and a second test pad;
an eighth wiring pattern electrically connected to the third wiring pattern and comprising a third test pad; and
a ninth wiring pattern electrically connecting the fourth wiring pattern and the fifth wiring pattern and comprising a fourth test pad,
wherein the first chip bonding pad, the second chip bonding pad, the third chip bonding pad and the fourth chip bonding pad are in the chip region to be electrically connected to the semiconductor chip,
wherein the first external connection pad and the second external connection pad are in the first bonding region,
wherein the third external connection pad and the fourth external connection pad are in the second bonding region, and
wherein the first test pad is in the first edge region, the third test pad and the fourth test pad are in the second edge region, and the second test pad is in the third edge region or the fourth edge region.

8. The chip mounted substrate of claim 7,
wherein the first external connection pad is closer to the chip region than the second external connection pad.

9. The chip mounted substrate of claim 8, wherein the first external connection pad and the second external connection pad are offset in the second direction.

10. The chip mounted substrate of claim 7,
wherein the third wiring pattern extends from the third chip bonding pad toward the second edge region, and the fourth wiring pattern extends from the fourth chip bonding pad toward the second edge region.

11. The chip mounted substrate of claim 10,
wherein the fifth wiring pattern is closer to the second edge region than the fourth wiring pattern.

12. The chip mounted substrate of claim 7,
wherein the fourth external connection pad is closer to the chip region than the third external connection pad.

13. The chip mounted substrate of claim 12,
wherein the third external connection pad and the fourth external connection pad are offset in the second direction.

14. The chip mounted substrate of claim 7, wherein the film-type substrate further comprises vias penetrating the insulating film and comprising:
a first via electrically connecting the first wiring pattern and the sixth wiring pattern;
a second via electrically connecting the second wiring pattern and the seventh wiring pattern;
a third via electrically connecting the third wiring pattern and the eighth wiring pattern;
a fourth via electrically connecting the fourth wiring pattern and the ninth wiring pattern; and
a fifth via electrically connecting the fifth wiring pattern and the ninth wiring pattern.

15. The chip mounted substrate of claim 7, further comprising:
a first protective layer on the upper surface of the insulating film to cover the upper wiring patterns, and exposing at least a portion of the first chip bonding pad, the second chip bonding pad, the third chip bonding pad, the fourth chip bonding pad, the first external connection pad, and the second external connection pad; and
a second protective layer on the lower surface of the insulating film to cover the lower wiring patterns, and exposing at least a portion of the first test pad, the second test pad, the third test pad, the fourth test pad, the third external connection pad and the fourth external connection pad.

16. The chip mounted substrate of claim 7, wherein the semiconductor chip comprises a display driver IC.

17. A chip mounted substrate comprising:
a film-type substrate a first edge and a second edge opposing in a first direction, and a third edge and a fourth edge connecting the first edge and the second edge and opposing in a second direction intersecting the first direction; and
a semiconductor chip on a chip region of the film-type substrate,
wherein the film-type substrate comprises:
an insulating film comprising an upper surface opposite a lower surface;
upper wiring patterns on the upper surface of the insulating film and comprising: a first wiring pattern comprising a first chip bonding pad; a second wiring pattern comprising a second chip bonding pad; a third wiring pattern comprising a third chip bonding pad and a first external connection pad; a fourth wiring pattern comprising a fourth chip bonding pad, and a fifth wiring pattern comprising a second external connection pad; and
lower wiring patterns on the lower surface of the insulating film, and comprising: a sixth wiring pattern electrically connected to the first wiring pattern and comprising a third external connection pad; a seventh wiring pattern electrically connected to the second wiring pattern and comprising a fourth external connection pad; eighth wiring pattern electrically connected to the third wiring pattern; and a ninth wiring pattern connecting the fourth wiring pattern and the fifth wiring pattern,
wherein the first chip bonding pad, the second chip bonding pad, the third chip bonding pad and the fourth chip bonding pad are in the chip region to be electrically connected to the semiconductor chip,
wherein the first external connection pad and the second external connection pad are in a first bonding region between the second edge and the chip region,
wherein the third external connection pad and the fourth external connection pad are in a second bonding region between the first edge and the chip region, and
wherein the sixth wiring pattern extends to the first edge, the eighth wiring pattern and the ninth wiring pattern extend to the second edge, and the seventh wiring pattern extends to the third edge or the fourth edge.

18. The chip mounted substrate of claim 17,
wherein the first external connection pad is closer to the chip region than the second external connection pad.

19. The chip mounted substrate of claim 17, further comprising:
a printed circuit board electrically connected to the first external connection pad and the second external connection pad; and
a display panel electrically connected to the third external connection pad and the fourth external connection pad.

20. The chip mounted substrate of claim 17, wherein a part of the film-type substrate is bent.
